(19) United States
(12) Patent Application Publication
(10) Pub. No.: US 2012/0036919 A1
(43) Pub. Date: Feb. 16, 2012

(54) NANOWIRE SENSOR HAVING A NANOWIRE AND ELECTRICALLY CONDUCTIVE FILM

(76) Inventors: Theodore I. Kamins, Palo Alto, CA (US); Philip J. Kuekes, Menlo Park, CA (US)

(21) Appl. No.: 13/264,701

(22) PCT Filed: Apr. 15, 2009
(86) PCT No.: PCT/US09/40686

§ 371 Date: Oct. 14, 2011

(51) Int. Cl. G01R 27/00; H01L 21/02

(52) U.S. Cl. 73/31.05; 438/49; 257/E21.002

(57) ABSTRACT

A nanowire sensor includes a first electrode, a second electrode, and a sensing element connecting the first electrode and the second electrode. The sensing element includes at least one nanowire connecting the first electrode and the second electrode and an electrically conductive film covering the at least one nanowire and extending between and contacting the first electrode and the second electrode, wherein conductance of the electrically conductive film is configured to change in the presence of at least one species to enable detection of the at least one species.

### BACKGROUND

Sensors for detecting species in fluids (gases or liquids) have become increasingly important in recent years for process control and personnel safety. Of particular importance are sensors that employ materials at nanoscale dimensions because they offer relatively large surface areas while occupying relatively small sizes, they exhibit relatively uniform properties, and they often have better performance than other types of sensors. For instance, the nanoscale sensors are more sensitive to chemical reactions with many target fluids than are other types of sensors to the same target fluids.

Nanoscale sensors are often configured to detect the species based upon sensing a property, such as, a change in electrical resistance. As such, the volume of the sensing element in the nanoscale sensors is often minimized to increase the surface to volume ratio, which for instance, increases the fraction of the volume that is affected by surface changes on the sensing element.

### BRIEF DESCRIPTION OF THE DRAWINGS

Embodiments are illustrated by way of example and not limited in the following figure(s), in which like numerals indicate like elements, in which:

FIG. 1 illustrates a cross-sectional side view of a nanowire sensor, according to an embodiment of the invention;

FIGS. 2A and 2B illustrate respective cross-sectional axial views of sensing elements, according to embodiments of the invention;

FIG. 3 illustrates a perspective view of an array, according to an embodiment of the invention;

FIG. 4A illustrates a diagrammatic view of an array, according to another embodiment of the invention;

FIG. 4B illustrates logic functions performed by the array shown in FIG. 4A, according to an embodiment; and

FIG. 5 illustrates a flow diagram of a method of forming a nanowire sensor.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is a nanowire sensor that includes a first electrode, a second electrode, and a sensing element connecting the first electrode and the second electrode. The sensing element is composed of at least one nanowire and an electrically conductive film covering the at least one nanowire and extending between and contacting the first electrode and the second electrode. According to an embodiment, the at least one nanowire may have a width in the range of about 5 nm to 500 nm. In another embodiment, the at least one nanowire may have a width in the range of about 10 nm to 200 nm. In addition, the at least one nanowire may have a length in the range of about 500 nm to 50 micrometers, and another embodiment, about 2 micrometers to 20 micrometers.

The conductance through the electrically conductive film alone or through the combination of the electrically conductive film and the nanowire is configured to change when at least one species interacts with the electrically conductive film. Consequently, the nanowire sensor disclosed herein may be implemented to determine a presence and, in certain instances, a quantity, of at least one species contained in a fluid (gas or liquid).

The at least one species may be any organic or inorganic material. In addition, the at least one species may be a charged or an uncharged species. In instances where the at least one species comprises charged species, the species that become attached to the electrically conductive film may cause a field effect to occur in the sensing element. The at least one species may also diffuse into the electrically conductive film and act as a dopant, changing the conductance (or conversely, the resistance) of the electrically conductive film. The change may occur throughout the film or, in some embodiments, at grain boundaries. In instances where the at least one species comprises uncharged species, the species that become attached or diffuse into the electrically conductive film may change the grain boundaries of the electrically conductive film, thus making it easier or more difficult for charge carriers to cross the grain boundaries of the electrically conductive film, which effectively changes the conductance (or conversely, the resistance) of the electrically conductive film. Interaction of the uncharged species with the conductive layer may also create a charged species which then interacts with the sensing element, as described above for a charged species.

In various embodiments, the at least one species attached to or embedded in the electrically conductive film may be removed. The at least one species may be removed through application of thermodynamic and/or kinetic effects on the electrically conductive film. For instance, the at least one species may be removed through application of a cleansing fluid over the nanowire sensor. However, where the at least one species has a relatively tight binding on the surface of the electrically conductive film, it may be necessary to add some additional energy to remove the at least one species. The additional energy may be imparted through, for instance, heating of the nanowire and the electrically conductive film by passing current through the nanowire and the electrically conductive film.

Alternatively, the bonds attaching the at least one species to the surface of the electrically conductive film may be broken by application of light waves when the bonds are sufficiently weak to enable such separation. As a further example, the pressure surrounding the electrically conductive film may be reduced to facilitate desorption of the at least one species from the electrically conductive film.

Thus, through application of various processes, the change in conductance through the electrically conductive film caused by the at least one species may be at least partially reversed by removing the at least one species. In some cases, the conductance of the electrically conductive film and, in certain instances, the underlying nanowire, may revert to the conductance prior to introduction of the at least one species.

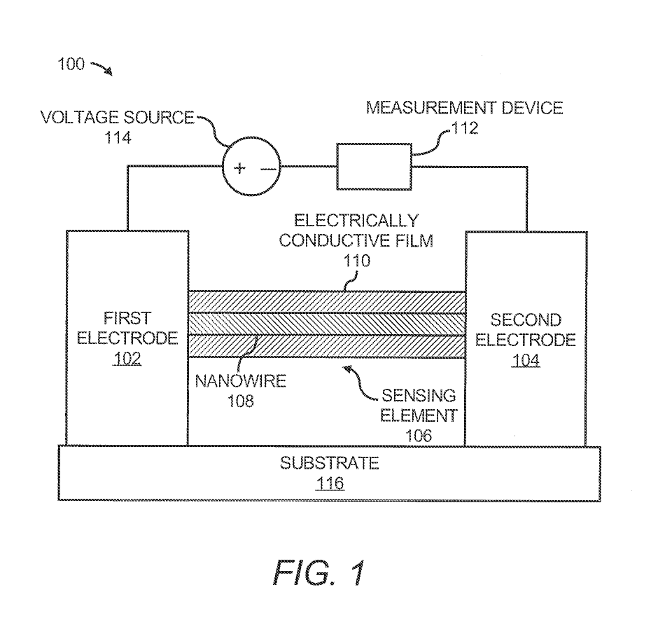

With reference first to FIG. 1, there is shown a cross-sectional frontal view of a nanowire sensor 100, according to an embodiment. It should be understood that the nanowire sensor 100 depicted in FIG. 1 may include additional components and that some of the components described herein may be removed and/or modified without departing from a scope of the nanowire sensor 100.

As depicted in FIG. 1, the nanowire sensor 100 includes a first electrode 102, a second electrode 104, and a sensing element 106. The sensing element 106 is depicted as being composed of a nanowire 108 covered by an electrically conductive film 110. In addition, the sensing element 106 is depicted as contacting and extending between the first electrode 102 and the second electrode 104. The sensing element 106 is further depicted as being suspended away from a surface of a substrate 116 on which the first electrode 102 and the second electrode 104 are located. In one regard, suspending the sensing element 106 away from a surface of the substrate 116 creates a larger surface area on the electrically conductive film 110 upon which species may become attached. Suspending the sensing element 106 also places the sensing element 106 further into the flow region so that the sensing element 106 is less affected by boundary-layer effects than if it were on the surface of the substrate 116. In other cases, the sensing element 106 is positioned on the surface of the substrate 116.

The nanowire sensor 100 is further depicted as including a measurement device 112 and a voltage source 114. According to an example, the measurement device 112 comprises a hardware device, such as, an ammeter. According to another example, the measurement device 112 is configured to perform additional processing operations and thus comprises a combination of hardware and software modules, the software comprising code stored, for instance, in a volatile or non-volatile memory, such as DRAM, EEPROM, MRAM, flash memory, floppy disk, a CD-ROM, a DVD-ROM, or other optical or magnetic media, and the like. By way of example, the measurement device 112 may be configured to analyze the information pertaining to detected currents through the electrically conductive film 110 alone or in combination with the nanowire 108.

In operation, the nanowire sensor 100 is configured to detect a species that is present in a fluid when the electrical conductance (or conversely, the electrical resistance) through the electrically conductive film 110 alone or in combination with the nanowire 108 changes. More particularly, the measurement device 112 may measure the electrical conductance (or resistance) of the sensing element 106 prior to introduction of a fluid containing the at least one species and may measure the electrical conductance after the fluid has been introduced. In this example, the electrically conductive film 110 may be configured to interact with particular types of species that may be contained in the fluid. If the electrical conductance of the electrically conductive film 110 changes, it is likely that the particular type of species is present in the fluid due to the interaction between the species and the electrically conductive film 110.

The effect the at least one species has on the conductance of the electrically conductive film 110 depends on the specific interaction of the at least one species with the electrically conductive film 110. More particularly, for instance, the electrical conductance of the electrically conductive film 110 may be altered by a charge on the surface of the electrically conductive film 110, by a charge diffusing into the electrically conductive film 110, by the uniformity with which the charge has diffused into the electrically conductive film 110 through the grains or along grain boundaries, etc. In other words, various types of species may interact differently with the same type of electrically conductive film 110. For instance, a first type of species may become attached to the surface of the electrically conductive film 110, whereas, a second type of species may diffuse into the electrically conductive film 110. Because the manner in which the electrical conductance of the electrically conductive film 110 becomes altered affects in different ways the electrical conduction in the electrically conductive film 110 and, in certain instances, the charge induced in the nanowire 108, detection of the electrical conductance may be used to differentiate between different species.

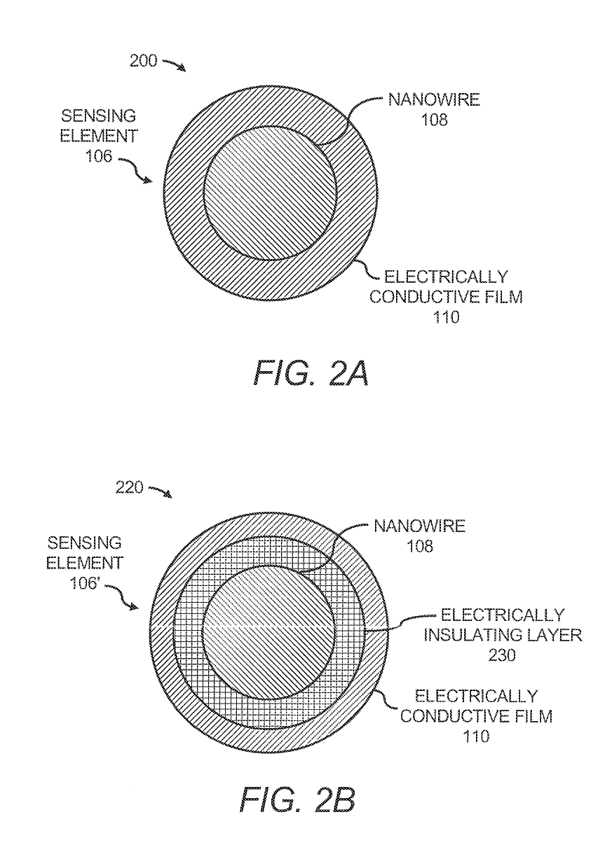

With reference now to FIGS. 2A and 2B, there are shown respective cross-sectional axial views 200 and 220 of the sensing element 106 depicted in FIG. 1, 106′, according to an embodiment. It should be understood that the nanowire 108 and the electrically conductive film 110 depicted in FIGS. 2A and 2B may include additional components and that some of the components described herein may be removed and/or modified without departing from a scope of the nanowire sensor 100 disclosed herein. For instance, a plurality of nanowires 108 and/or a plurality of layers of electrically conductive film 110 may be provided in place of the nanowire 108 and the electrically conductive film 110. In another example, although the nanowire 108 in FIGS. 2A and 2B have been shown to have a circular cross section, it should be understood that the nanowire 108 may have other cross sectional shapes, such as a hexagonal shape, a square shape, a trapezoidal shape, a faceted surface, an irregular shape, etc.

As shown in FIG. 2A, the nanowire 108 and the electrically conductive film 110 are coaxial electrical conductive regions. The conductance of the nanowire 108 is based upon factors including the geometry, the resistivity, and the thickness of the materials that comprise the nanowire 108. The nanowire 108 may comprise any suitable material for forming nanowires, such as, silicon, boron, germanium, GaAs, InP, other III-V and II-VI compounds, etc. Similarly, the conductance of the electrically conductive film 110 is based upon factors including the geometry, the resistivity, and the thickness of the materials that comprise the electrically conductive film 110. The electrically conductive film 110 may comprise any suitable material, such as, tin oxide, zinc oxide, other metal oxides, etc. By varying the factors that affect the conductance of the nanowire 108 and the conductance of the electrically conductive film 110, the ratio of conductance between the nanowire 108 and the electrically conductive film 110 may be altered.

The ratio of conductance between the nanowire 108 and the electrically conductive film 110 may be also be altered by controlling the number of dopant atoms that are added during growth of the nanowire 108 as described in greater detail herein below. In one regard, the electrically conductive film 110 may be configured to have a relatively higher conductance level as compared with the nanowire 108 to thus enable changes in the electrical conductance through the electrically conductive film 110 to be more readily identified.

As shown in FIG. 2B, in addition to the nanowire 108 and the electrically conductive file 110, the sensing element 106′ includes an electrically insulating layer 230. The electrically insulating layer 230 may comprise any suitable material for at least partially reducing electrical conduction between the nanowire 108 and the electrically conductive film 110. In addition, the insulating layer 230 may extend at least partially between the first electrode 102 and the second electrode 104.

In either or both of the sensing elements 106, 106′, the electrically conductive film 110 may also be functionalized, by which molecules or other substances are attached to a surface of the electrically conductive film 110. The electrically conductive film 110 may be functionalized by, for instance, the addition of materials that enable the electrically conductive film 110 to interact with a particular type of species. According to an example, the electrically conductive film 110 may be functionalized to at least one of prevent attachment of species other than at least one particular species and vary sensitivity to different species.

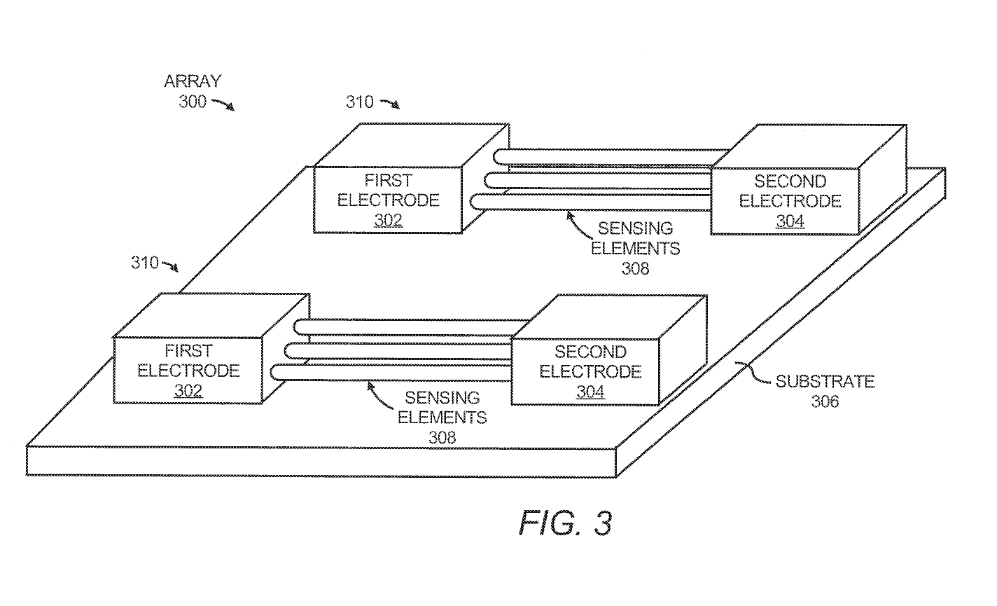

With reference now to FIG. 3, there is shown a perspective view of a nanowire sensor array 300 employing a plurality of nanowire sensors 310, according to an embodiment. It should be understood that the nanowire sensor array 300 depicted in FIG. 3 may include additional components and that some of the components described herein may be removed and/or modified without departing from a scope of the nanowire sensor array 300.

As depicted in FIG. 3, the array 300 includes a plurality of nanowire sensors 310 positioned on a substrate 306. Although two nanowire sensors 310 have been depicted in FIG. 3, the nanowire sensor array 300 may include additional nanowire sensors 310. Each of the nanowire sensors 310 is depicted as including a first electrode 302, a second electrode 304 and multiple sensing elements 308 connecting the first electrode 302 and the second electrode 304. Although not particularly shown, each of the multiple sensing elements 308 is formed of either or both of the sensing elements 106, 106′ depicted in FIGS. 2A and 2B.

Although the first electrodes 302 and the second electrodes 304 of the nanowire sensors 310 are depicted in FIG. 3 as being in the same horizontal plane, it should be understood that the first electrodes 302 and the second electrodes 304 may also be in different planes. For example, the second electrode 304 may be vertically aligned above the first electrode 302 with the sensing elements 308 extending vertically to connect the two electrodes 302 and 304. In other examples, the first and second electrodes 302 and 304 may be offset with respect to each other to make electrical connection easier or to be compatible with nanowire 108 growth directions.

According to a first example, the electrically conductive films 110 of each of the plurality of sensing elements 308 are composed of the same or similar material with respect to each other. In addition, the nanowires 108 of each of the plurality of sensing elements 308 are composed of the same or similar material with respect to each other. In addition, or alternatively, the electrically conductive films 110 of the sensing elements 308 may be doped and/or functionalized in similar manners with respect to each other to enable the electrically conductive films 110 to interact in one or more manners with the same or similar types of species. As a further alternative, the electrically conductive films 110 of the sensing elements 308 may be doped and/or functionalized in different manners with respect to each other to enable electrically conductive films 110 formed of different materials to interact with the same or similar types of species.

According to another example, at least one of the plurality of nanowire sensors 310 is differently configured from at least another one of the plurality of nanowire sensors 310. In this example, at least one of the nanowire sensors 310 includes sensing elements 308 that differ from the sensing elements 308 of another one of the nanowire sensors 310. The sensing elements 308 may differ through being composed of nanowires 108 formed of differing materials, electrically conductive films 110 formed of differing materials, differing functionalization and/or doping, etc.

The array 300 may have differing nanowire sensor arrays 310 to detect multiple types of species. For instance, each differently configured nanowire sensor 310 may be configured to detect a different type of species. According to an example, the differently configured nanowire sensors 310 may be employed to identify false positives by verifying and/or removing certain positive identifications detected by the sensing elements 308. In addition, further differentiation between detected species may be obtained by observing the response to the selective desorption of particular species by photons of selected wavelengths.

Electronic circuitry may be integrated on the substrate 306. These electronics may be used, for instance, to amplify the small signals from the multiple nanowire sensors 310, to compare the signals to a reference structure not exposed to the at least one species, to convert analog signals to digital signals, etc. In addition, the electronic circuitry may be used to determine the concentration of each species in test gases from the different responses of each of the nanowire sensors 310 of the array 300.

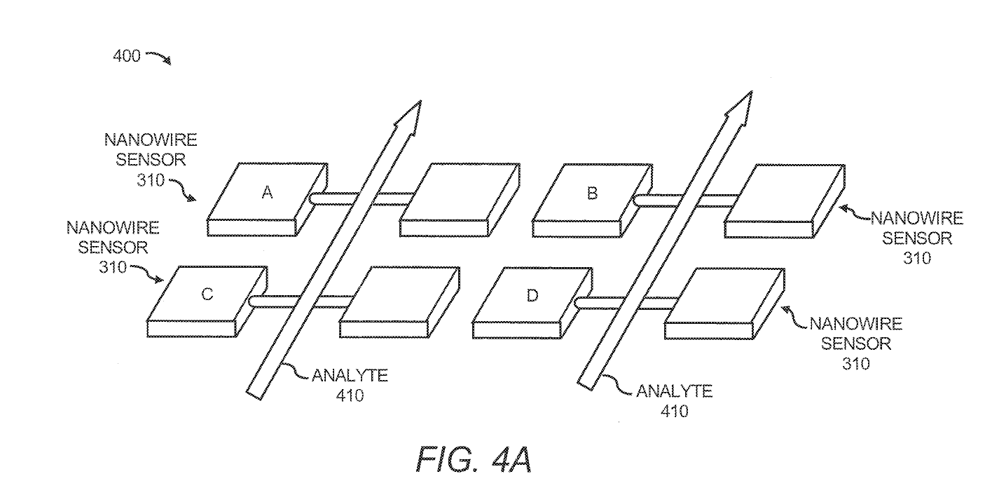

FIG. 4A illustrates a diagrammatic view of a nanowire sensor array 400, according to an embodiment. As shown, the nanowire sensor array 400 includes a plurality of nanowire sensors 310. The array 400 has differently configured nanowire sensors 310 as indicated by the labels “A, B, C, and D”. While the array 400 is depicted with four nanowire sensors 310, a person having ordinary skill in the art will appreciate that the array 400 may have any number of differently configured nanowire sensors 310 arranged in any configuration. Moreover, the array 400 may include other components not illustrated in FIG. 4A, such as the measurement device 112 described above, with respect to FIG.

The differently configured nanowire sensors 310 may be configured to interact with species 1, 2, 3, and 4, respectively. For example, an analyte 410 may be exposed to the array 400, such that the analyte 410 flows and contacts each of the differently configured nanowire sensors 310 (A, B, C, and D), as indicated by the arrows shown in FIG. 4A. The array 400 may detect four different species because the array 400 may contain four differently configured nanowire sensors 310, each of which being capable of interacting with a different species.

Logic may be built into the array 400, such that the array 400 performs an operation equivalent to a logic gate as a result of an exposure of the array 400 to an analyte. The operation may result in an indication that certain species may be present in the analyte 410. For example, the array 400 may be exposed to an analyte 410 containing some or all of species 1, 2, and 3. These species may interact with the differently configured nanowire sensors A, B, or C and may change the differently configured nanowire sensors A, B, or C from a non-conducting state to a conducting state, or otherwise vary the conductance through the nanowire sensors 310.

FIG. 4B shows an example of the logic functions 450 performed by the nanowire sensor array 400. For example, pairs of the differently configured nanowire sensors 310 A, B, C, and D in the nanowire sensor array 400 perform an AND function, as illustrated by AND gates 430 and 431, respectively. For example, if differently configured nanowire sensors 310 A and B interact with species 1 and 2, respectively, species 1 and 2 have been detected. If differently configured nanowire sensors 310 C and D interact with species 3 and 4, respectively, species 3 and 4 have been detected. Because differently configured nanowire sensors 310 A and B are connected in parallel with differently configured nanowire sensors 310 C and D, which is represented by the OR gate 420 in FIG. 4B, if either differently configured nanowire sensors 310 A, and B and differently configured nanowire sensors 310 C, and D are conducting, species (1 and 2) or species (3 and 4) are detected.

Conversely, in other embodiments, the differently configured nanowire sensors 310 A, B, C, and D may be “turned off” as a result of an interaction between a species and a differently configured nanowire sensors 310. That is, the differently configured nanowire sensors 310 A, B, C, and D are designed so that current flows through the nanowire sensors 310 before the nanowire sensor array 400 is exposed to an analyte 410. However, the differently configured nanowire sensors 310 A, B, C, and D may be configured such that the interaction of a species and a nanowire sensor 310 substantially reduces the current flowing through the sensing element 308. In this embodiment, each pair of the differently configured nanowire sensors 310 A, B, C, and D functions as an OR gate and the connection in parallel performs the function of an AND gate. Different connections of nanowire sensors 310 to perform other logical functions are possible, as will be evident to a person of ordinary skill in the art.

A smaller amount of higher quality information is obtained from the nanowire sensor array 400, as compared to the combination of conventional sensors needed to accomplish the same detection. The number of electronic signals that need to be transported and the amount of required computation external to the nanowire sensor array 400 is reduced by performing some of the computation within the array 400 itself. For example as illustrated in FIG. 4B, if the conductance of either differently configured nanowire sensors 310 A and B or differently configured nanowire sensors 310 C and D are above a threshold, then the array 400 may indicate simply that either species 1 and 2 or species 3 and 4 caused the signal, and, thus, that either species 1 and 2 or species 3 and 4 are present in the analyte 410. Further calculations performed external to the array 400 are thus not required to obtain an accurate result.

Moreover, the array 400 is extremely sensitive allowing for the detection of a small quantity of a species in a fluid, because the nanowire sensors 310 A, B, C, and D provide a large surface area relative to the volume of the nanowire, where the fluid may interact with the sensing elements 308. Detection often relies on sensing a property such as a change in conductance, so the volume of the nanowire sensors 310 A, B, C, and D may be reduced as much as feasible to increase the surface to volume ratio and, therefore, the fraction of the volume that is affected by surface charges.

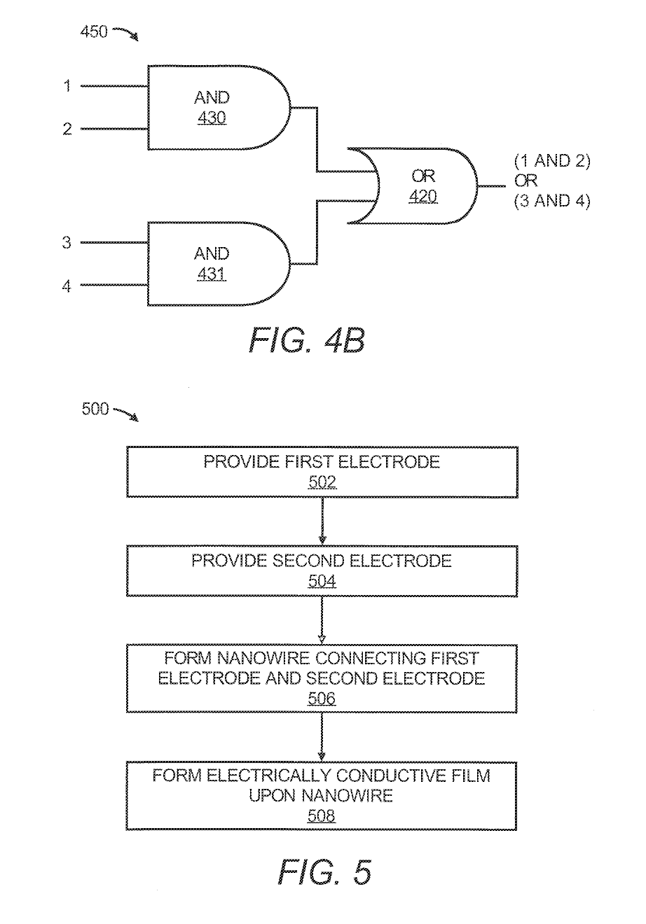

Turning now to FIG. 5, there is shown a flow diagram of a method 500 of fabricating nanowire sensors 100 and 310 according to an embodiment. It should be understood that the method 500 of fabricating the nanowire sensors 100 and 310 depicted in FIG. 5 may include additional steps and that some of the steps described herein may be removed and/or modified without departing from a scope of the method 500. Thus, for instance, the nanowire 108 may be formed prior to the formation of the first electrode 102 and the second electrode 104.

At step 502, a first electrode 102 is formed through any suitable formation process, such as one or more of, growing, chemical vapor deposition, sputtering, etching, lithography, etc.

At step 504, a second electrode 104 is formed through any suitable formation process, such as one or more of, growing, chemical vapor deposition, sputtering, etching, lithography, etc. According to an example, steps 502 and 504 are performed concurrently.

At step 506, a nanowire 108 connecting the first electrode 102 and the second electrode 104 is formed through any suitable formation process, such as one or more of, metal catalyzed nanowire growth, chemical vapor deposition, sputtering, etching, lithography, etc. According to an example, at least one other process that adds material for forming the nanowire 108 may be performed at step 506. The nanowire 108 may be suspended between the first electrode 102 and the second electrode 104 as depicted in FIG. 1 either during growth of the nanowire 108 or after the nanowire 108 has been formed.

During formation of the nanowire 108, a dopant may be added in order to vary the conductance of the nanowire 108. The dopant may be a p-type dopant or an n-type dopant and may be added in the gas phase. For instance, where the nanowire 108 comprises boron, diborane (B₂H₆) may be added as p-type dopant. Alternatively, the dopant may be added after the nanowire 108 is formed.

At step 508, the electrically conductive film 110 is formed on the nanowire 108 through any suitable process or combination of processes, such as chemical vapor deposition, physical vapor deposition, chemical reaction, diffusion, masking, etc.

During formation of the electrically conductive film 110 or after its formation, a dopant may be added in order to vary the conductance of the electrically conductive film 110. The dopant may be a p-type dopant or an n-type dopant and may be added in the gas phase during deposition or it may be added after deposition. The conductance of the electrically conductive film 110 may also be altered where the formation process alters the microstructure of the electrically conductive film 110. After formation of the electrically conductive film 110, the electrically conductive film 110 may be functionalized so that it interacts with one or a selected group of species in the analyte.

An array 300 of differently configured nanowire sensors 310 may be formed where each nanowire sensor 310 or set of nanowire sensors 310 is selectively coated with a different electrically conductive film 110, with the electrically conductive film 110 limited to the selected set of nanowire sensors 310 by any of a number of different methods. For instance, the electrically conductive film 110 may be applied to one set of nanowire sensors 310 by a technique analogous to ink-jet printing at the selected set of nanowire sensors 310. Alternately, the other sets of nanowire sensors 310 may be masked by a physical shadow mask or covered with a protective layer so that the electrically conductive film 110 is only deposited on the desired set of nanowire sensors 310. A protective coating may be applied to the entire array 300 of nanowire sensors 310 and then removed selectively from one set by ultraviolet photon desorption focused on the selected set of nanowire sensors 310 or by current passing through the nanowires 108 of the selected set of nanowire sensors 310.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

1. A nanowire sensor comprising:
a first electrode;
a second electrode; and
a sensing element connecting the first electrode and the second electrode, wherein the sensing element is comprised of at least one nanowire connecting the first electrode and the second electrode and an electrically conductive film covering the at least one nanowire and extending between and contacting the first electrode and the second electrode, wherein conductance of the electrically conductive film is to change in the presence of at least one species to enable detection of the at least one species.

2. The nanowire sensor according to claim 1, further comprising:
a measurement device configured to detect a change in conductance of the electrically conductive film, wherein the change in conductance is to indicate the presence of the at least one species.

3. The nanowire sensor according to claim 1, wherein the at least one nanowire comprises a material selected from the group consisting of silicon, boron, germanium, GaAs, InP, and other III-V and II-VI compounds, and wherein the electrically conductive film comprises a material selected from the group consisting of tin oxide, zinc oxide, and other metal oxides.

4. The nanowire sensor according claim 1, wherein the electrically conductive film is functionalized to interact with at least one particular species.

5. The nanowire sensor according to claim 1, wherein the electrically conductive film is to at least one of prevent attachment of species other than at least one particular species and vary sensitivity to different species.

6. The nanowire sensor according to claim 1, wherein the electrically conductive film is configured for removal of the at least one species through at least one of application of heat to the electrically conductive film and application of a cleansing fluid over the electrically conductive film.

7. The nanowire sensor according to claim 1, further comprising a plurality of sensing elements connecting the first electrode and the second electrode, wherein each of said plurality of sensing elements is comprised of a nanowire and an electrically conductive film.

8. The nanowire sensor according to claim 7, wherein at least one of the plurality of sensing elements is configured differently as compared with another one of the plurality of sensing elements.

9. The nanowire sensor according to claim 1, wherein conductance of the at least one nanowire is to change in the presence of at least one species to enable detection of the at least one species.

10. The nanowire sensor according to claim 1, wherein the sensing element further comprises an electrically insulating layer positioned between the at least one nanowire and the electrically conductive film.

11. A nanowire sensor array comprising:
a plurality of the nanowire sensors, wherein each of the plurality of nanowire sensors comprises:
a first electrode;
a second electrode; and
a sensing element connecting the first electrode and the second electrode, wherein the sensing element is comprised of at least one nanowire connecting the first electrode and the second electrode and an electrically conductive film covering the at least one nanowire and extending between and contacting the first electrode and the second electrode, wherein conductance of the electrically conductive film is to change in the presence of at least one species to enable detection of the at least one species.

12. The nanowire sensor array according to claim 11, wherein the nanowire sensor array forms part of a logic circuit.

13. A method of fabricating a nanowire sensor, said method comprising:
providing a first electrode;
providing a second electrode;
forming a nanowire to connect the first electrode with the second electrode; and
coating the nanowire with the electrically conductive film, wherein conductance of the electrically conductive film is to change in the presence of at least one species to enable detection of the at least one species.

14. The method of fabricating the nanowire sensor-according to claim 13, said method further comprising:
providing an electrically insulating layer to cover the nanowire; and
wherein coating the nanowire with the electrically conductive film further comprises coating the electrically insulating layer with the electrically conductive film.

15. The method of fabricating the nanowire sensor according to claim 13, said method further comprising:
providing an array of nanowire sensors; and
selectively coating nanowire sensors with an electrically conductive film.
